(19) United States
(12) Patent Application Publication
(10) Pub. No.: US 2003/0030987 A1
(43) Pub. Date: Feb. 13, 2003

(54) Method and apparatus for pumped liquid cooling

(76) Inventors: Jon Zuo, Lancaster, PA (US); Brian D. Fritsch, Columbia, PA (US)

Correspondence Address: Samuel W. Apicelli, Duane Morris LLP, 305 N. Front Street, P.O. Box 1003, Harrisburg, PA, 17108-1003, US

(21) Appl. No.: 10/255,429

(22) Filed: Sep. 26, 2002

Related U.S. Application Data
(62) Division of application No. 09/925,106, filed on Aug. 9, 2001.

(51) Int. Cl. H05K 7/20

(52) U.S. Cl. 361/723

(57) ABSTRACT

A method and apparatus for cooling heat-producing equipment, the method comprising the steps of directing heat from the heat producing equipment to a cooling loop and, circulating liquid through said cooling loop from a liquid reservoir to a radiator structure. In a first exemplary embodiment, the apparatus comprises a liquid reservoir, a pump, a radiator and a plurality of interface members. In a second exemplary embodiment, the apparatus comprises a liquid reservoir, a pump, a radiator and an air-to-liquid heat exchanger.

### FIELD OF THE INVENTION

The present invention relates to a method and apparatus for removing heat from electronic equipment, and in particular, a method and apparatus for removing heat from a plurality of circuit cards disposed in an electronics cabinet.

### BACKGROUND OF THE INVENTION

Cooling systems for electronics are well known. Devices such as heat pipes, thermal fins, and pumped cooling systems have been used to provide cooling for electronic equipment such as processors, circuit cards and integrated circuits. For example, U.S. Pat. No. 5,343,940 describes a flexible heat transfer device for cooling electronic elements disposed on circuit boards. Similarly, U.S. Pat. Nos. 5,884,693 and 6,076,595 to Austin et al. teach a heat pipe enclosure which is used to cool electronics disposed within the enclosure. Finally, U.S. Pat. No. 5,890,371 discloses a hybrid air conditioning system for cooling heat-producing equipment such as electronics.

U.S. Pat. No. 6,208,510 describes a cooling system for cooling an integrated test cell 10. The test cell 10 includes a plurality of electronic circuit boards 18 disposed in card cages 14, 16. In order to keep these circuit boards 18 cool, a liquid-liquid heat exchanger 46 is disposed above the circuit boards. The heat exchanger 46 takes heated air produced by the circuit boards 18 and heats liquid disposed therein. This heated liquid is then passed to a thermal controller 52 (basically a housing filled with chilled liquid) through liquid line 50. The heated liquid is cooled at the thermal controller 52 and is passed back to the heat exchanger 46 through liquid line 48. In this way, liquid is continually circulated from the heat exchanger 46 to the thermal controller 52 and back again. Cooled air which passes out of the heat exchanger 46 reaches a circulation unit 58 (e.g., fan) which forces the cooled air to be re-circulated back to a bottom side of the circuit boards 18.

However, all of the above-described patented systems fail to adequately cool electronics with speed and efficiency. In particular, the cooling system described in the '510 patent fails to adequately cool the circuit cards 18 due at least in part to the inefficient placement of-the circulation unit 58 and the heat exchanger 46. Further, the fact that the heat exchanger 46 comprises an air-liquid to liquid-liquid unit, significantly reduces the cooling properties of the cooling system.

Thus, there is presently a need for a cooling system which quickly and efficiently cools electronic equipment.

### SUMMARY OF THE INVENTION

The present invention is method and apparatus for cooling heat-producing equipment, the method comprising the steps of directing heat from the heat producing equipment to a cooling loop and, circulating liquid through said cooling loop from a liquid reservoir to a radiator structure.

The above and other advantages and features of the present invention will be better understood from the following detailed description of the exemplary embodiments of the invention which is provided in connection with the accompanying drawings.

### BRIEF DESCRIPTION OF THE DRAWINGS

FIG. 1 is a block diagram showing an electronics cabinet and cooling system according to a first exemplary embodiment of the present invention.

FIG. 2 is a block diagram showing an electronics cabinet and cooling system according to a second exemplary embodiment of the present invention.

### DETAILED DESCRIPTION

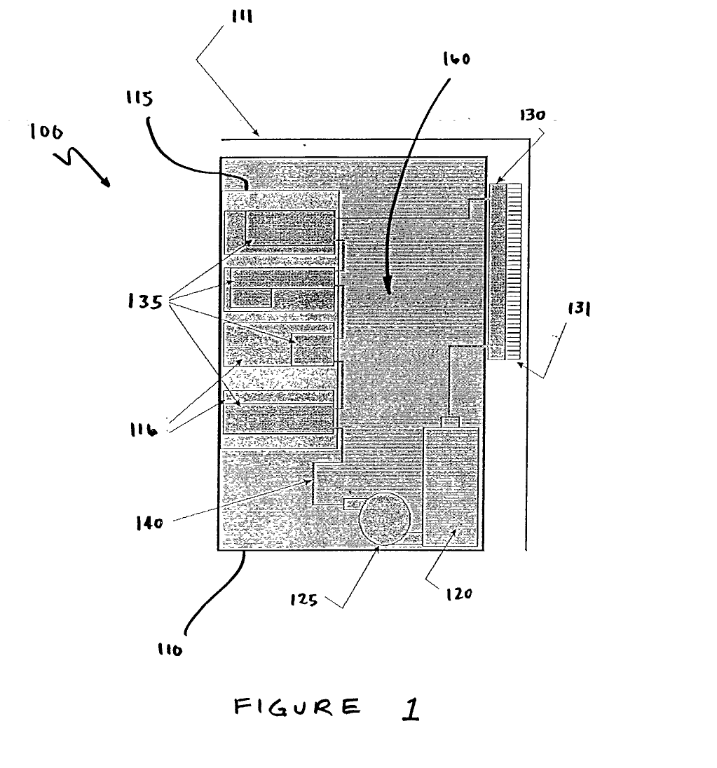

Referring to FIG. 1, there is shown a cooling system 100 according to a first exemplary embodiment of the present invention. The cooling system 100 includes a housing 110 containing heat-producing equipment 115. In the first exemplary embodiment, the heat-producing equipment 115 comprises circuit boards 116 with heat-producing circuits disposed thereon, however, the heat-producing equipment 115 may comprise many different kinds of equipment, as will be understood by those skilled in the art. The cooling system 100 also may include a solar shield 111 which at least partially surrounds the housing 110, and which protects the housing from the heating rays of the sun.

The cooling system 100 also includes a reservoir 120 of liquid, a pump 125, a radiator structure 130, interface members 135, and tubing 140 coupling the reservoir to the interface members. The reservoir 120, pump 125, radiator structure 130 and tubing 140 combine to form a ‘cooling loop’ 160. In the first exemplary embodiment, the interface members 135 also form part of the cooling loop 160. The tubing 140 may be made of any suitable material, but is preferably made of plastic or Copper (Cu). Moreover, the liquid disposed in the reservoir 120 may be any type of liquid, but is preferably chilled water or anti-freeze.

The interface members 135 preferably comprise laminates of heat conducting material (e.g., Copper) with liquid flow channels disposed therein. The liquid flow channels are preferably coupled to the tubing 140, so that liquid from the reservoir 120 may be pumped therethrough. The liquid present in the flow channels of the interface members 135 is heated by the circuit boards 116, and is transferred through the cooling loop 160 by the pump 125. In this manner, the interface members 135 conduct heat generated by the circuit boards 116 away from the circuit boards and into the cooling loop 160. The heated liquid is then moved to the radiator structure 130 where the heat is dissipated into the ambient air by convection. The interface members 135 may be customized and sized to fit the circuits, circuit boards, or other heat-producing equipment 115 to which they are attached. The interface members 135 may be attached to the respective heat-producing equipment 115 via a strap or tie, mechanical fasteners, and/or pressure sensitive adhesive (PSA).

The radiator structure 130 preferably comprises a laminate of heat conducting material (e.g., Copper). The radiator structure 130 may also include a plurality of fins 131 as shown in FIG. 1, for further assisting in conducting heat away from the housing 110. The fins 131 increase the surface area of the radiator structure 130, thereby permitting more heat to be dissipated. The radiator structure 130 is preferably disposed between the solar shield 111 and an exterior wall of the housing 110. The radiator structure 130 may be attached to the exterior wall of the housing 110 or suspended from the exterior wall by fastening means (e.g., mechanical fasteners, PSA, etc.). Connecting the radiator structure in this manner allows the wall of the housing 110 to become a heat transfer surface under natural or forced convection conditions.

The system 100 pumps liquid from the reservoir 120 via tubing 140 to the interface members 135. Liquid passes through the interface members 135, thus absorbing the heat generated by the circuit boards 116. The fluid continues to be pumped to the radiator structure130, where the heat is released to the outside environment by convection.

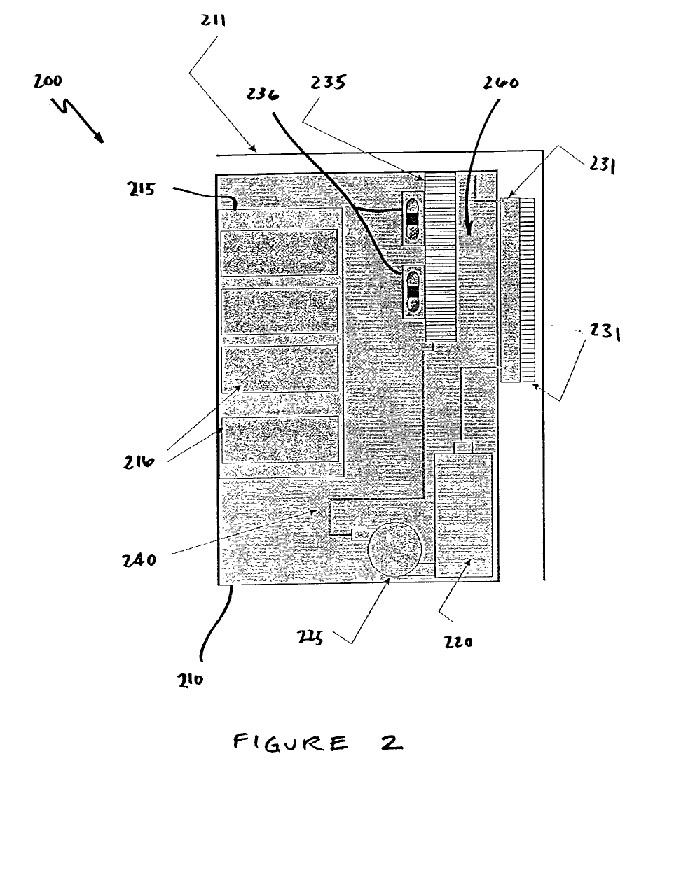

Referring to FIG. 2, there is shown a cooling system 200 according to a second exemplary embodiment of the present invention. The cooling system 200 includes a housing 210 containing heat-producing equipment 215. In the second exemplary embodiment, the heat-producing equipment 215 comprises circuit boards 216, with heat-producing circuits disposed thereon, however, the heat-producing equipment 215 may comprise many different kinds of equipment, as will be understood by those skilled in the art.

The cooling system 200 also includes a reservoir 220 of liquid, a pump 225, a radiator structure230, an air-to-liquid heat exchanger 235, a circulation unit 236, and tubing 240 coupling the reservoir to the other portions. The reservoir 220, pump 225, radiator structure 230 and tubing 240 combine to form a ‘cooling loop’ 260. In the second exemplary embodiment, the air-to-liquid heat exchanger 235 also forms part of the cooling loop 260. The tubing 240 may be made of any suitable material, but is preferably made of plastic or Copper (Cu). Moreover, the liquid disposed in the reservoir 220 may be any type of liquid, but is preferably chilled water or anti-freeze.

The air-to-liquid heat exchanger 235 preferably comprises a mechanism for accepting heated air and transferring heat from such heated air to liquid through a heat exchanger core. Accordingly, the air-to-liquid heat exchanger 235 may comprise a heat pipe or other equivalent structure. The circulation unit 236 (e.g. fan) disposed adjacent to the air-to-liquid heat exchanger 235 serves to transmit heat from the heated air produced by the heat producing equipment 115 to the air-to-liquid heat exchanger.

The radiator structure 230 preferably comprises a laminate of heat conducting material (e.g., Copper). The radiator structure 230 may also include a plurality of fins 231 as shown in FIG. 2, for further assisting in conducting heat away from the housing 210. The radiator structure 230 is preferably disposed between the solar shield 211 and an exterior wall of the housing 210. The radiator structure 230 may be attached to the exterior wall of the housing 210 or suspended from the exterior wall by fastening means (e.g., mechanical fasteners, PSA, etc.). Connecting the radiator structure in this manner allows the wall of the housing 210 to become a heat transfer surface under natural or forced convection conditions.

The radiator structure 230, along with air-to-liquid heat exchanger 235, creates an air-to-liquid, liquid-to-air (AL/LA) heat transfer path which is superior to most conventional heat transfer systems. This AL/LA transfer path quickly and efficiently transfers heat away from the housing 210. The AL/LA transfer path provides significant advantages over conventional heat transfer systems (e.g., the air-to-liquid, liquid-to-liquid (AL/LL) transfer path proposed in U.S. Pat. No. 6,208,510 discussed above), as it allows more flexibility in the packaging of the cooling system 200. In particular, separating the air-to-liquid (AL) unit from the liquid-to-air (LA) unit, and connecting those units through a tubing loop, allows the separate units to be placed virtually anywhere within the cooling system 200, thus greatly expanding the design possibilities for the cooling system (i.e., the design is not limited to particular placements of the air-to-liquid and liquid-to-air units).

Moreover, the specific placement of the circulation unit 236 between the heat producing equipment 215 (e.g., circuit boards 216) and the air-to-liquid heat exchanger 235 permits the second exemplary embodiment to transfer heat away from the heat producing equipment with more speed and efficiency than in conventional designs. For example, in U.S. Pat. No. 6,208,510, the heat exchanger (46) is disposed between the circulation unit (56) and the circuit cards (18), thus substantially limiting airflow from the circuit cards to the heat exchanger. In other words, heated air from the circuit cards (18) must travel around the heat exchanger (46) in order for the circulation unit (56) to be effective. In the second exemplary embodiment, there is nothing to block the airflow from the circuit boards 216 to the heat exchanger 235, and thus, heat can be transferred more quickly and efficiently.

The system 200 pumps liquid from the reservoir 220 via tubing 240 to the air-to-liquid heat exchanger 235. Liquid passes through the air-to-liquid heat exchanger 235, thus absorbing the heat generated by the circuit boards 216. The fluid continues to be pumped to the radiator structure 230, where the heat is released to the outside environment by convection.

Although the above discussion refers to interface members 135 which preferably comprise laminates of Copper, it will be noted by those skilled in the art that such interface members may be formed of laminates of plastic and/or other polymers.

Although the invention has been described in terms of exemplary embodiments, it is not limited thereto. Rather, the appended claims should be construed broadly, to include other variants and embodiments of the invention which may be made by those skilled in the art without departing from the scope and range of equivalents of the invention

What is claimed is:

1. A method for cooling heat-producing equipment, comprising the steps of:
directing heat from the heat producing equipment to a cooling loop; and,
circulating liquid through said cooling loop from a liquid reservoir to a radiator structure.

2. The method of claim 1, wherein said step of directing heat to a cooling loop comprises coupling said heat producing equipment to said cooling loop through at least one interface member.

3. The method of claim 2, wherein said at least one interface member comprises at least one laminate.

4. The method of claim 1, wherein the step of directing heat to a cooling loop comprises directing heated air produced by the heat producing equipment to an air-to-liquid heat exchanger, said air-to-liquid heat exchanger being coupled to said cooling loop.

5. The method of claim 1, wherein said cooling loop comprises a liquid reservoir, a pump, a radiator structure, and a length of tubing arranged in a loop.

6. The method of claim 5, wherein said cooling loop further comprises an air-to-liquid heat exchanger.

7. A cooling system comprising:
at least one cooling loop adapted to be coupled to heat producing equipment;
at least one reservoir of liquid coupled to the at least one cooling loop at a first position and a second position; and,
at least one pump for pumping liquid from the reservoir through the cooling loop from the first position to the second position.

8. The cooling system of claim 7, further comprising:
at least one interface member coupled to said cooling loop, said at least one interface member providing an interface between the heat producing equipment and the cooling loop.

9. The cooling system of claim 8, wherein said at least one interface member comprises at least one laminate.

10. The cooling system of claim 7, further comprising:
a radiator structure coupled to the cooling loop at a position between the at least one reservoir and the at least one pump.

11. The cooling system of claim 7, further comprising:
at least one air-to-liquid heat exchanger coupled to said cooling loop, said at least one air-to-liquid heat exchanger providing an interface between the heat producing equipment and the cooling loop.

12. The cooling system of claim 11, further comprising:
at least one air circulation unit disposed between the heat producing equipment and the air-to-liquid heat exchanger, so as to direct heated air towards the air-to-liquid heat exchanger.

13. An electronics cabinet comprising:
at least one circuit card disposed within a housing;
at least one-cooling loop coupled to the at least one circuit card;
at least one reservoir of liquid coupled to the at least one cooling loop at a first position and a second position; and,
at least one pump for pumping liquid from the reservoir through the cooling loop from the first position to the second position.

14. The electronics cabinet of claim 13, further comprising:
a solar shield disposed around the housing.

15. A cooling system comprising:
a liquid reservoir;
a pump coupled to the liquid reservoir at a first position;
a radiator structure coupled to the reservoir at a second position; and
tubing coupling the pump to the radiator structure,
wherein the liquid reservoir, the pump, and the tubing are arranged in a circular manner to form a cooling loop.

16. The cooling system of claim 15, further comprising:
at least one interface member coupled to the cooling loop between the pump and the radiator structure.

17. The cooling system of claim 15, further comprising:
at least one air-to-liquid heat exchanger coupled to the cooling loop between the pump and the radiator structure.

18. The cooling system of claim 17, further comprising:
at least one circulation unit disposed between the at least one air-to-liquid heat exchanger and heat producing equipment to be cooled by the cooling system.
